(19) United States
(12) Patent Application Publication
(10) Pub. No.: US 2019/0165189 A1
(43) Pub. Date: May 30, 2019

(54) BUS BAR FOR USE IN FLEXIBLE PHOTOVOLTAIC MODULES

(71) Applicant: Miasolé Hi-Tech Corp., Santa Clara, CA (US)

(72) Inventors: Jason Stephen Corneille, San Jose, CA (US); James Teixeira, San Jose, CA (US)

(21) Appl. No.: 15/826,316

(22) Filed: Nov. 29, 2017

(51) Int. Cl. H01L 31/02; H01L 31/047; H01L 31/048; H01L 31/05

(52) U.S. Cl. CPC H01L 31/0201; H01L 31/05; H01L 31/048; H01L 31/047

(57) ABSTRACT

Disclosed are flexible photovoltaic modules that have photovoltaic cells electrically connected to each other and positioned in a sealed space between flexible top and bottom sheets and that includes a first region at a first end of the module, a second region at a second end of the module, and a central region interposed between the first and second regions that encompasses at least 75% of the cells, and a bus bar with interlaced copper strands, an external insulation, a length of at least 1 meter and a thickness of about 0.5 millimeters or less, a conductivity that can conduct at least 3.0 amps of current, that extends substantially the length of the module, is positioned in the first region, the central region, and the second region, and is electrically connected, in the first region, to a second external electrical connector, and, in the second region, to the cells.

### BACKGROUND

Photovoltaic technology is being rapidly adopted to generate electricity from solar energy, both for local use and for supplying power to electrical grids. Photovoltaic systems may be implemented on structures, such as buildings and houses. In addition, light weight photovoltaic modules are now being adopted for transportation applications such as trucks, cars, and boats. Photovoltaic cells are the basic units of such systems. One or more photovoltaic cells are typically arranged into a photovoltaic module, which may be then used to form a photovoltaic array.

### SUMMARY

In one embodiment, a flexible photovoltaic module with a length and a width may be provided. The flexible photovoltaic module may include a flexible top sheet, a flexible bottom sheet, a plurality of photovoltaic cells electrically connected to each other and positioned in a sealed space between the flexible top sheet and the flexible bottom sheet. The sealed space may include a first region at a first end of the flexible photovoltaic module, a second region at a second end of the flexible photovoltaic module, and a central region interposed between the first region and the second region that encompasses at least 75% of the photovoltaic cells. The flexible photovoltaic module may also include a first external electrical connector that extends into the first region and is electrically connected, in the first region, to the plurality of photovoltaic cells, a second external electrical connector that extends into the first region and a bus bar that includes interlaced copper strands and an external insulation, has a length of at least 1 meter and a thickness of about 0.5 millimeters or less, has a conductivity that can conduct at least 3.0 amps of current, extends substantially the length of the flexible photovoltaic module and is positioned in the first region, the central region, and the second region, and is electrically connected, in the first region, to the second external electrical connector, and, in the second region, to the plurality of photovoltaic cells.

In some embodiments, an outer surface of the flexible top sheet within the central region may vary in planarity by less than 5% of planar.

In some such embodiments, each of the photovoltaic cells may include a photovoltaic layer and may be positioned such that the photovoltaic layer faces the flexible top sheet, and the bus bar may be positioned in-between the plurality of photovoltaic cells and the flexible bottom sheet.

In some embodiments, the interlaced copper strands may be flattened.

In some embodiments, an outer surface of the flexible bottom sheet within the central region may vary in planarity by less than 5% of planar.

In some embodiments, an outer surface of the flexible top sheet within the central region may vary in planarity by less than 5% of planar and an outer surface of the flexible bottom sheet within the central region may vary in planarity by less than 5% of planar.

In some embodiments, the bus bar may be configured to deform in a direction parallel to the flexible top sheet more than in a direction perpendicular to the flexible top sheet.

In some embodiments, repeated heating and cooling of the flexible photovoltaic module does not cause the bus bar to plastically deform one or more of the flexible top sheet and the flexible bottom sheet.

In some embodiments, the length of the flexible photovoltaic module may be at least 1.7 meters long.

In some embodiments, the length of the flexible photovoltaic module may be between about 1.7 meters long and 6 meter long, and the length of the bus bar may be at least 75% of the length of the flexible photovoltaic module.

In some embodiments, the bus bar may have a width of at least 4 millimeters.

In some embodiments, the interlaced copper strands may be plated by titanium nitride.

In some embodiments, the first external electrical connector and the second external electrical connector may have opposite polarities.

In some embodiments, the plurality of photovoltaic cells may be electrically connected to each other in series.

In some such embodiments, the plurality of photovoltaic cells may include N photovoltaic cells, the first photovoltaic cell may be positioned in the first region, and the Nth photovoltaic cell may be positioned in the second region.

In some such embodiments, the bus bar may be physically connected to the Nth photovoltaic cell.

In some embodiments, the bus bar may be an electrical return for the plurality of photovoltaic cells.

In some embodiments, the flexible photovoltaic module may further include a plurality of electrical interconnects, the plurality of photovoltaic cells may be electrically interconnected to each other by the plurality of electrical interconnects such that each electrical interconnect forms an electrical connection between two photovoltaic cells, and the bus bar may not electrically interconnect two of the photovoltaic cells together.

In some such embodiments, each electrical interconnect may be a current collector for each corresponding photovoltaic cell such that the current generated by each of the photovoltaic cells is collected by the plurality of electrical interconnects and the bus bar may not be a current collector for the plurality of photovoltaic cells.

In some embodiments, the first region may include one photovoltaic cell, the second region may include another photovoltaic cell, and the central region may include the remaining photovoltaic cells of the plurality of photovoltaic cells.

### BRIEF DESCRIPTION OF THE DRAWINGS

FIG. 1 depicts a top view of an example flexible photovoltaic module.

FIG. 2 depicts a cross-sectional side view of the module 100 of FIG. 1.

FIG. 3 depicts an example electrical schematic of the module of FIG. 1.

FIG. 4A depicts partial cross-sectional views of an example solid bus bar undergoing an example thermal cycle.

FIG. 4B depicts partial cross-sectional views of another example solid bus bar undergoing an example thermal cycle.

FIG. 4C depicts an illustration of the thermal expansion of a bus bar in a module.

FIGS. 5A and 5B depict top views of x-rays of metallic bus bars.

FIG. 6 depicts a photograph of a portion of an example uninsulated bus bar that includes interlaced metallic strands.

FIG. 7 depicts a photograph of a portion of another example uninsulated bus bar that includes interlaced metallic strands.

FIG. 8 depicts an example cross-sectional area of a bus bar that has interlaced metallic strands.

### DETAILED DESCRIPTION

In the following description, numerous specific details are set forth in order to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Flexible photovoltaic modules are made of flexible materials that allow these modules to bend and conform to various non-planar installation surfaces. Such modules can include two flexible sealing sheets and a set of flexible photovoltaic cells sealed between these sheets. Flexible modules may be easier to handle and install than their rigid glass counterparts. For example, flexible modules are less susceptible to damage when dropped or stepped on. Further, such modules may be positioned directly onto supporting surfaces without any intermediate mounting hardware. Flexible materials used for constructing photovoltaic modules may be easier to cut or otherwise shape to fit these modules into available installation areas. Flexible sealing sheets may be bonded directly to various installation surfaces, such as rooftop polymer membranes, and may be used for additional protection of these surfaces after installation. Further, a sealed space formed between the installation surface and the flexible module may be used to house and protect various components of a photovoltaic array, such as connectors, lines, inverters, converters, and the like.

Flexible photovoltaic modules allow new photovoltaic applications, not available with conventional rigid modules. For example, flexible modules may be used on substantially horizontal rooftops, which are common on commercial buildings. Horizontal rooftops use different roofing materials and are subject to different environmental conditions than the typically sloped rooftops of residential buildings. For example, flat horizontal rooftops tend to accumulate water and snow. Freezing and thawing cycles cause substantial thermal and mechanical stresses to be exerted on rooftop structures. Further, flat rooftops may have greater temperature fluctuations because of their construction material. Flat roofs are often used as walkways to different parts of the roof. Photovoltaic modules used on horizontal rooftops may need to withstand exposure to rain, snow, stresses associated with freeze and thaw cycles, temperature fluctuations, and foot traffic.

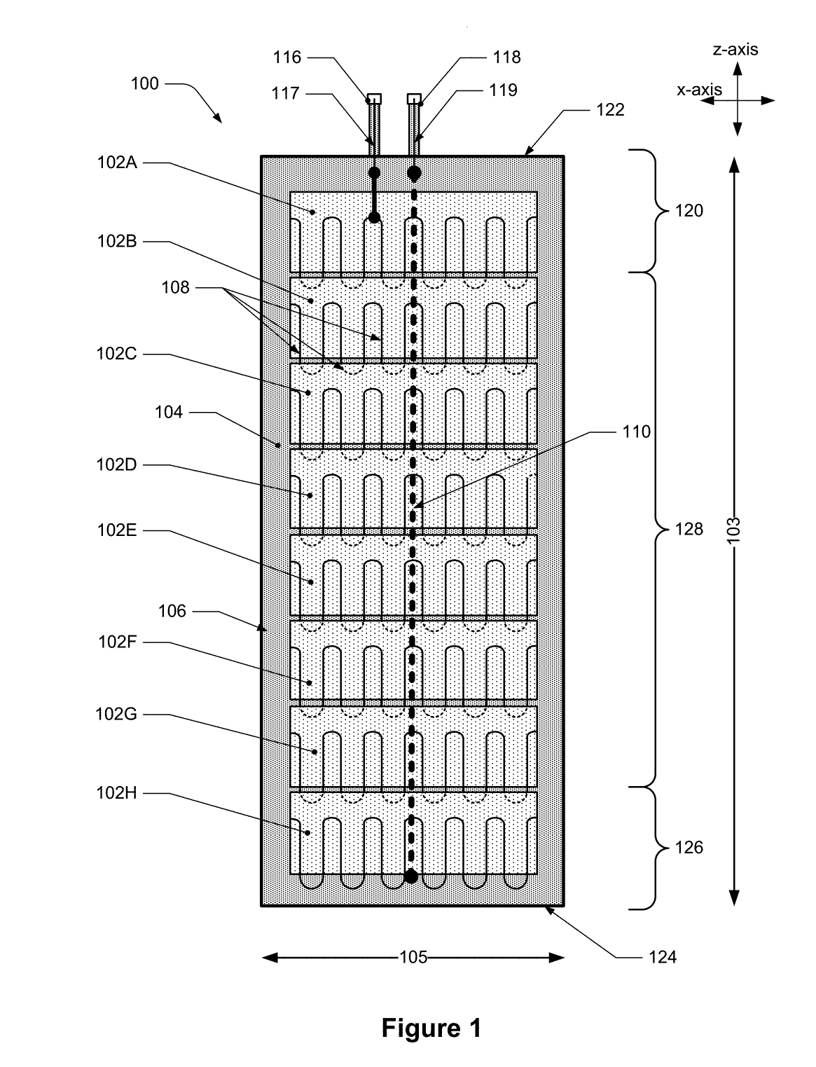

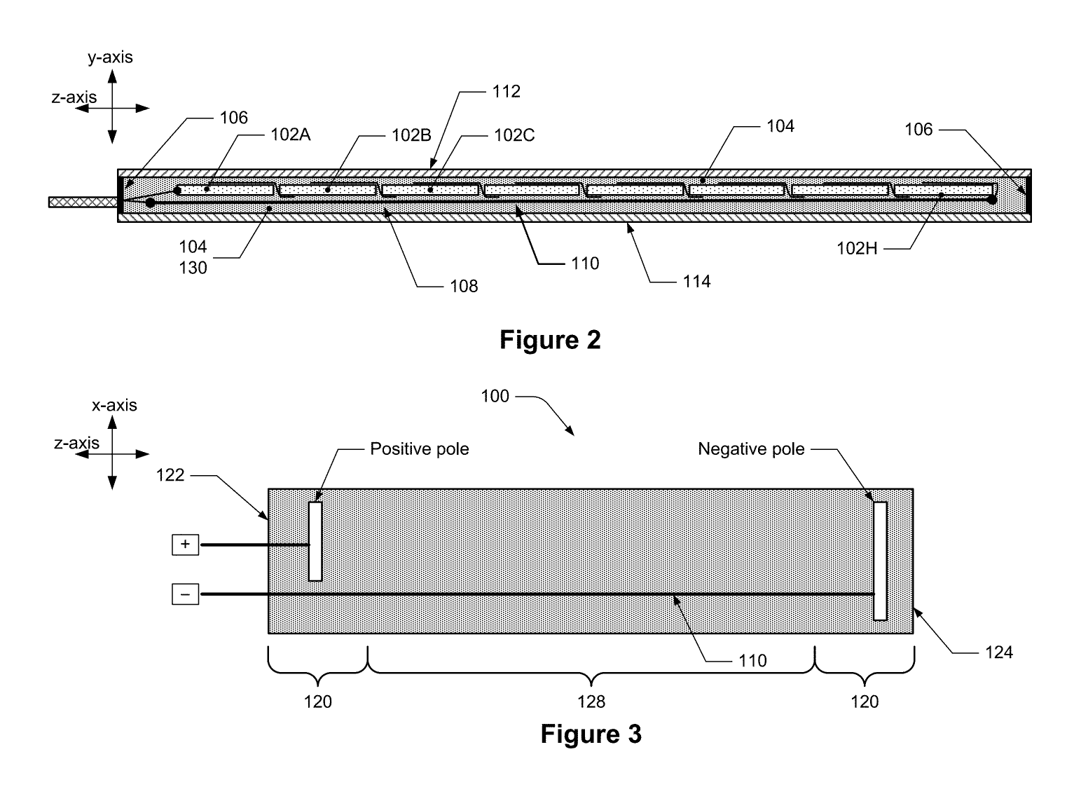

An example embodiment of a flexible photovoltaic module that is the subject of the present disclosure will now be discussed. FIG. 1 depicts a top view of an example flexible photovoltaic module 100 while FIG. 2 depicts a cross-sectional side view of the module 100 of FIG. 1. As can be seen in FIG. 1, the example flexible photovoltaic module 100 (referred to herein as “module 100”) includes a flexible top sheet (not labeled in FIG. 1, 112 in FIG. 2), a flexible bottom sheet (not labeled in FIG. 1, 114 in FIG. 2), a sealed space 104, eight photovoltaic cells 102 (labeled 102A-102H) positioned within the sealed space 104, an edge seal 106, and various electrical components, including a wire network 108 and a bus bar 110, that are described in more detail below. The bus bar is generally positioned between the flexible bottom sheet and the photovoltaic cells 102; it is depicted in FIG. 1 as a heavy dotted line. The module 100 includes a length 103 in the z-axis of FIG. 1 and a width 105 in the x-axis of FIG. 1. The y-axis of the module 100 is at a direction perpendicular to the flexible top sheet 112 and the flexible bottom sheet 114 as seen in FIG. 2. These axes are applicable throughout the Figures.

In FIG. 2, the flexible top sheet 112 and the flexible bottom sheet 114 can be seen vertically offset from each other in the y-axis, the sealed space 104 is located between the flexible top and flexible bottom sheets 112 and 114, the photovoltaic cells 102 are positioned within the sealed space 104. As seen in FIG. 2, two portions of the edge seal 106, shown at each end of the module 100, span between the flexible top sheet 112 and the flexible bottom sheet 114 and form a part of exterior edge surfaces of the module 100. Here, the flexible top sheet 112 and the flexible bottom sheet 114 are substantially the same size (same length and width) and are substantially aligned with each other. Substantially here means within +/−5% in size and alignment.

The sealed space 104, identified in dark shading in FIGS. 1 and 2, is in-between the flexible top sheet 112 and the flexible bottom sheet 114. This sealed space 104 may be considered a plenum that is bounded, in whole or in part, by the flexible top sheet 112, the flexible bottom sheet 114, and the edge seal 106. The edge seal 106 is depicted in FIG. 1 as the edge around the module 100 (i.e., the solid black edge of the module 100). The edge seal 106 may extend along one or more edges of, and may span between, the first sheet and the second sheet; it may also form a portion of the exterior surface of the module 100. It is understood that the edge seal 106 may also form a portion of the exterior surface of the module 100 as well as define a boundary of the sealed space 104.

The flexible top sheet 112 may be considered a light-facing sheet. The flexible top sheet 112 and flexible bottom sheet 114 may be sealing sheets that include flexible materials, such as polyethylene, polyethylene terephthalate (PET), polypropylene, polybutylene, polybutylene terephthalate (PBT), polyphenylene oxide (PPO), polyphenylene sulfide (PPS) polystyrene, polycarbonate (PC), ethylene-vinyl acetate (EVA), fluoropolymers (e.g., polyvinyl fluoride (PVF), polyvinylidene fluoride (PVDF), ethylene-terafluoethylene (ETFE), fluorinated ethylene-propylene (FEP), perfluoroalkoxy (PFA) and polychlorotrifluoroethane (PCTFE)), acrylics (e.g., poly(methyl methacrylate)), silicones (e.g., silicone polyesters), and polyvinyl chloride PVC, as well as multilayer laminates and co-extrusions of these materials. A typical thickness of a sealing sheet is between about 125 microns and 2,540 microns or, more specifically, between about 254 microns and 1,270 microns, though other thicknesses may be used as well. In certain embodiments, a flexible sealing sheet includes a metallized layer to improve its water permeability characteristics. For example, a metal foil may be positioned in between two insulating layers to form a composite flexible sealing sheet.

In certain embodiments, the flexible top sheet 112 may be made from material that is different than a material of the flexible bottom sheet 114, and the flexible top and bottom sheets 112 and 114 may be of different thicknesses from each other. In some embodiments, these sheets may have a thickness less than 2,032 microns or, more specifically, less than 1,016 microns or even less than 508 microns.

In certain embodiments, the module 100 may have an encapsulant layer positioned in between the flexible top sheet 112 and the photovoltaic cells 102, as well as another encapsulant layer between the flexible bottom sheet 114 and the photovoltaic cells 102. One or more of the encapsulant layers may also be positioned around portions of the bus bar 110. Examples of encapsulant layer materials include non-olefin thermoplastic polymers or TPO, such as polyethylene (e.g., a linear low density polyethylene), polypropylene, polybutylene, PET, PBT, polystyrene, polycarbonates, fluoropolymers, acrylics, ionomers, silicones, and combinations thereof.

As noted above, the module 100 may include the edge seal 106 that surrounds and seals the photovoltaic cells 102 together with the flexible top sheet 112 and the flexible bottom sheet 114, as well as with other components. The edge seal 106 may prevent moisture from penetrating towards the photovoltaic cells 102. The edge seal 106 may be made from one or more organic or inorganic materials that have low inherent water vapor transmission rates. In certain embodiments, a portion of the edge seal 106 that contacts electrical components (e.g., bus bars, diodes, return lines) of module 100 is made from a thermally resistant polymeric material. The edge seal 106 may also secure flexible top sheet 112 with respect to the flexible bottom sheet 114. In certain embodiments, the edge seal 106 determines at least some of the boundaries of the sealed space 104.

In some embodiments, the module 100 may be manufactured using one or more lamination procedures in which aspects of the module 100 may be heated and pressed. For example, the pressing may be performed by an inflatable bladder, and such lamination may heat the encapsulant and edge seal such that the sealed space 104 is formed in the module 100.

The module may be considered to have three regions, with the first region 120 located at the first end 122 of the module as shown in FIG. 1. In the example of FIG. 1, the first region 120 includes the first end of the module 100, some of the sealed space 104, and at least a portion of one photovoltaic cell 102A. At the opposite end of the module 100 is a second region 126 which includes the second end 124, some of the sealed space 104, and at least a portion of photovoltaic cell 102H. In between these two regions is the central region 128, which includes the majority of the module. For the purposes of this description, a central region of the module may include more than 50%, and in some embodiments, at least 75% of the photovoltaic cells (as well as the other corresponding module components like the associated wire networks 108) of the module 100; the first and second regions 120 and 126 include the remaining area of the module. As discussed further below, characterizing a module as being divided into three regions is useful to discuss placement of the bus bar 110 in the module.

The electrical components and configurations of the module 100 will now be discussed. In FIGS. 1 and 2, the eight photovoltaic cells 102 (labeled 102A-102H in FIG. 1) are positioned within the sealed space 104 and electrically interconnected and may or may not be physically overlapping. The photovoltaic cells 102 may be any appropriate solar cells, and in some embodiments, may be flexible photovoltaic cells. A flexible photovoltaic cell is one that can be flexed without damage. Examples of flexible photovoltaic cells include copper indium gallium selenide (CIGS) cells, cadmium-telluride (Cd—Te) cells, amorphous silicon (a-Si) cells, micro-crystalline silicon (Si) cells, crystalline silicon (c-Si) cells, gallium arsenide (GaAs) multi-junction cells, light adsorbing dye cells, and organic polymer cells. A photovoltaic cell has a photovoltaic layer that generates a voltage when exposed to light. The photovoltaic layer may be positioned adjacent to a back conductive layer, which, in certain embodiments, is a thin flexible layer of a metal such as molybdenum (Mo), niobium (Nb), copper (Cu), silver (Ag), and combinations and alloys thereof. The photovoltaic cell may also include a flexible conductive substrate, such as stainless steel foil, titanium foil, copper foil, aluminum foil, or beryllium foil. Additional examples of a flexible conductive substrate include a layer of a conductive oxide or metal over a polymer film, such as polyimide. In certain embodiments, a substrate has a thickness of between about 50 microns and 1,270 microns (e.g., about 254 microns), with other thicknesses also in the scope of the embodiments described herein. The photovoltaic cell may also include a top flexible conductive layer. This layer can include one or more transparent conductive oxides (TCO), such as zinc oxide, aluminum-doped zinc oxide (AZO), indium tin oxide (ITO), and gallium doped zinc oxide. A typical thickness of a top conductive layer is between about 100 nanometers and 1,000 nanometers or, more specifically, about 200 nanometers and 800 nanometers.

Photovoltaic cells may be interconnected by any appropriate conductor that contacts a front side (i.e., the photovoltaic layer that is exposed to light and generates a voltage) of one cell as well as back side of an adjacent cell to interconnect these two cells in-series. In the example of FIG. 1, an electrical connection between two photovoltaic cells 102 is made using a wire network 108. The wire networks 108 are examples of electrical interconnects. Wire networks 108 each extend over a front side of one photovoltaic cell as well as under a back side of an adjacent cell to electrically interconnect these two photovoltaic cells in-series. In some embodiments, an interconnect may also function as a current collector; in the example of FIG. 1, the wire network 108 collects current generated by a photovoltaic cell. In some embodiments, the wire network 108 includes a metal wire that is partially embedded in a polymer layer and positioned onto both the front side and back side of two adjacent photovoltaic cells. For example, wire network 108 identified in FIGS. 1 and 2 may collect the current from photovoltaic cell 102B and interconnect photovoltaic cells 102B and 102C.

The shaped wire shown in FIG. 1 is an example of an interconnect and current collector. Other configurations of these components may also be used. For example, in some embodiments, a short piece of thin wire may extend between adjacent cells to interconnect them, with a separate current collector overlying the cells.

Given the nature of interconnects, current collectors, and bus bars, it is generally not feasible to interchange a current collector or interconnect with a bus bar, and vice versa. For example, some electrical interconnects are thin wires that travel a short distance between two adjacent cells, such as 5 mm, 20 mm, or even up to 500 mm. It is advantageous to have these wires very thin, such as about 36 standard wire gauge (SWG) to about 46 SWG, because this small size can reduce the surface area of a photovoltaic cell that is blocked or shadowed by the interconnect and therefore increase efficiency of the photovoltaic cell. It is also advantageous to have these interconnects travel short distances, such as no greater than two times the width of the cell. However, as the thickness and cross-sectional area of the interconnect decreases, so does the conductivity of that interconnect. An interconnect carries the current generated by the two interconnected photovoltaic cells. For thin wire interconnects, a single section of a thin wire may be too small to carry the current. Multiple thin wires, or multiple sections of a single wire, can be used to provide capacity to carry the current generated by the two photovoltaic cells.

Similarly, it is also advantageous to have current collectors be thin, small wires. For optimized and efficient current collection from a photovoltaic cell, it is generally advantageous to have a current collector positioned on various locations of the photovoltaic cell in order to minimize resistive losses and maximize module efficiency as compared to aperture efficiency. But because the current collector is placed directly on the photovoltaic cell, it is advantageous to minimize the surface area of the photovoltaic cell that is blocked or shadowed by the current collector to thereby increase efficiency of the photovoltaic cell. In some instances it has been found that using about a 36 SWG to about 46 SWG, as compared to wires thicker than these gauges in the same configuration, can lead to an increase in efficiency of about 2% to 5%. Like described above, as the thickness and cross-sectional area of the current collector decreases, so does the conductivity of that current collector. The current collector as a whole must be able to carry the current generated by the photovoltaic cell, but for thin wire current collectors, a single section of a thin wire is typically too small to carry the required current. Accordingly, multiple thin wires, or multiple sections of a single wire, are used for the current collector of a photovoltaic cell.

Conversely, a bus bar that is used as an electrical return for a series of interconnected photovoltaic cells that extends for the substantial length of the module, as discussed herein, generally has a much larger cross-sectional area than current collectors and interconnects for several reasons. For example, the bus bar has a cross-sectional area sufficient to carry a current generated by all the photovoltaic cells to which it is electrically connected. This cross-sectional area may be about 2 to 2.5 square millimeters as compared to a 36 SWG wire that has a cross-sectional area of about 0.0293 square millimeters or a 46 SWG wire that has cross-sectional area of about 0.0029 square millimeters. Additionally, the bus bar must be able to withstand the physical and thermal forces associated with being positioned within the module and extending for substantially the entire length of the module, such as modules greater than 1 meter in length. A thin wire used for an interconnect or current collector would not be able to withstand the current generated by an entire string of cells as well as the thermal cycling and associated physical and thermal forces which would cause such a bus bar to break or fail within the module. Accordingly, it would not be feasible to use a single interconnect wire or a current collector as a return bus bar for a photovoltaic module having a length of at least 1 meter and a plurality of photovoltaic cells.

The overall electrical arrangement between the photovoltaic cells of the module may be in-series, parallel, or a combination of both. For example, the photovoltaic cells 102 of module 100 may all be electrically connected in-series. This in-series arrangement may result in string of photovoltaic cells having opposite polarities at each end of the string and at opposite ends of the module. For instance, referring to FIG. 1, the string of photovoltaic cells 102 may have one polarity at the first end 122 of the module 100 and the opposite polarity at the second end 124 of the module 100. In FIG. 1, the photovoltaic cell 102A may have a positive polarity while the photovoltaic cell 102H may have the negative polarity. FIG. 3 depicts an example electrical schematic of the module of FIG. 1. As can be seen, the positive pole is located at the first end 122 (within the first region 120) of the module 100 and the negative pole is located at the second end 124 (within the second region 126).

It can advantageous to have the external electrical connections of the module at one end of the module. To have both negative and positive poles at the same end of the module, an electrical return line is used to provide an electrical pathway for one of the poles to the opposite end of the module. The bus bar 110 depicted in FIGS. 1-3 provides a return line for the string of photovoltaic cells 102. In FIG. 1, the module 100 includes a single bus bar 110, shown in a heavy dotted line, that serves as the return line for the module 100. As seen in FIG. 2, the bus bar 110 is positioned between the string of photovoltaic cells 102 and the flexible bottom sheet 114. The bus bar 110 is positioned in the module 100 such that it extends for about substantially the length of the module 100. Here, substantially means at least 85%. In some embodiments, the bus bar may extend at least 90% or 95% of the length of the module. As can be seen in FIG. 1, the bus bar 110 extends from the first region 120, through the central region 128, and into the second region 126. The bus bar 110 is also seen electrically connected to photovoltaic cell 102H; this electrical connection may be made in the second region 126 and may be made using a solder connection directly between the bus bar 110 and an electrical component of the photovoltaic cell 102H, or indirectly between these two components such as by using a small electrical wire or other connector.

Referring to FIG. 3, the bus bar 110 serves as the electrical return for the negative pole from the second end 124 of the module 100 to the first end 122 of the module 100. Often, though not necessarily, the bus bar 110 is electrically connected to the photovoltaic cell that is last in the string of photovoltaic cells. For instance, if there are N photovoltaic cells, such as 30, then the bus bar is electrically connected to the Nth, or 30^{th}, photovoltaic cell; such electrical connection may be made within the second region 126 of the module 100.

The current generated by the module 100 may be transferred to elements external to the module 100, such as other modules in an array of photovoltaic modules, inverters, or a power grid. To form the connections between the module 100 and these external elements, the module may have one or more electrical connectors that are accessed during installation and connected to the external elements, such as electrical connectors of adjacent modules. A module's electrical connectors include electrically conductive elements, such as a metallic wire that may be electrically insulated. An electrical connector may also include, or may be configured to make electrical connections to, standard MC4 photovoltaic connectors or other types of external photovoltaic connectors. For example, a module may have a cable connected to a photovoltaic connector that is electrically connected to the photovoltaic cells such that electricity generated by the cells can be transported to the cable, the photovoltaic connector and to an external electrical connection, such as another module.

The one or more electrical connectors of a flexible photovoltaic module may be electrically connected to the photovoltaic cells that are sealed inside the module and to return lines provided within the module that typically extend along the module. The one or more electrical connectors may be electrically connected to the photovoltaic cells by electrical leads. An electrical lead may have a portion that extends into the sealed space of the module, which may include extending through an edge seal of the module. Electrical leads may be in the form of thin but sufficiently conductive metal strips that may have flat aspect ratios (i.e., their heights may be substantially smaller (e.g., less than 10%) than their widths). In some of the embodiments disclosed herein, the height of an electrical lead may be 0.1 millimeters or 0.125 millimeters, while the width may be 12 mm. An electrical lead may be positioned within a module during manufacturing such that one portion of an electrical lead is located within a sealed space of the module with another portion extending through and outside the sealed space so that it may electrically connect with an electrical connector.

For example, as can be seen further in FIG. 1, the module 100 includes a first external electrical connector 116 and a second external electrical connector 118 that are both located at the first end 122 of the module 100. The first external electrical connector 116 has a first electrical lead 117 that extends through the edge seal 106, into the sealed space 104, and is electrically connected to the photovoltaic cell 102A. This electrical connection between these two elements is made within the first region 120 and may be made using a solder connection directly between the first electrical lead 117 and an electrical component of the photovoltaic cell 102A, or indirectly between these two components such as by using a small electrical wire or other conductive connector. The second external electrical connector 118 has a second electrical lead 119 that extends through the edge seal 106, into the sealed space 104, and is electrically connected to the photovoltaic cell 102H through the bus bar 110, which serves as the electrical connection pathway between these two elements as discussed above.

Modules that are arranged like that in FIGS. 1 and 2, i.e., that have an in-series string of photovoltaic cells with only two external electrical connectors at one end of the module, present unique challenges for transporting all of the current generated by the string of photovoltaic cells to the end of the module having the external electrical connectors. For instance, the various materials combined into such thin flexible modules, including the encapsulant, the bus bar, the wire networks, the flexible top and bottom sheets, may have significant differences in their coefficients of thermal expansion (CTE). The differences are more significant because of the tight physical coupling of these systems. CTE differences may cause substantial mechanical stress on electrical connections and other elements of flexible photovoltaic modules, and the flexibility of the module itself may not be sufficient to accommodate such stresses.

For some thin flexible modules that use a solid bus bar that extends substantially the length of the module, like depicted in FIG. 1, these CTE differences have caused some undesirable effects, including a “bus bar bump,” which may result after the module is subjected to repeated thermal cycling, i.e., repeatedly heating and cooling of the module. As used herein, the term “solid bus bar” means a bus bar that is a monolithic metal band, ribbon, or strip, or a bus bar that is substantially monolithic which means, for instance, a segmented bus bar that has segments of monolithic metal electrically connected by flexible connectors (e.g. a wire or a solder connection). The cross-sectional area of this monolithic metal band taken in any plane perpendicular to its length is not hollow and does not contain gaps or spaces.

The differences in CTEs between the bus bar and other materials of the module cause plastic deformation of the module in areas surrounding the bus bar that are undesirable for the module, such as an undesirable aesthetic which may affect the marketability of the module.

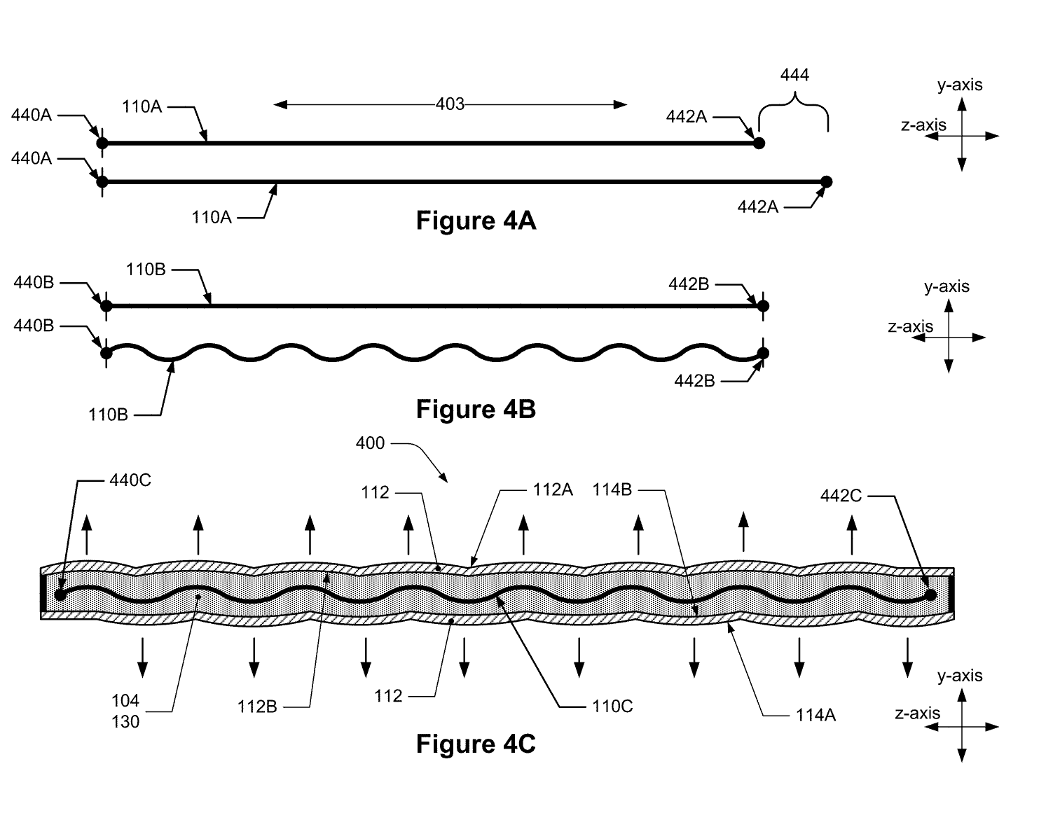

FIG. 4A depicts partial cross-sectional views of an example solid bus bar undergoing an example thermal cycle. This series of Figures illustrate the formation of a bus bar bump that is caused by the thermal cycling of a module having a solid bus bar. The partial module depicted in FIG. 4C may be considered similar to module 100 described herein, except that the bus bar 110 is a solid bar as discussed above (e.g., solid metal or segmented) and even though some aspects may be omitted and the Figure may have a different scale. The view of these Figures is along a direction parallel to the width of the module, i.e., along the x-axis of FIGS. 1-3. FIG. 4A illustrates the thermal expansion of a bus bar when at least one end of the bus bar is not in a fixed position. As seen in FIG. 4A, solid bus bar 110A at the top of the Figure is depicted outside a module and its first end 440A is fixed in space but its second end 442A is not fixed such that it may move in the z-axis. When the solid bus bar 110A is subjected to an increase in temperature, the CTE of the solid bus bar 110A causes it to expand in the x-, y-, and z-axes, but the effect of the this expansion is most significant in its length 403 in the z-axis because that is the largest dimension of the bus bar 110A. For instance, the CTE of a bus bar that has a length of 1 meter, a width of 4 millimeters, and a thickness of 0.5 millimeters, will cause the largest increase in its length as compared to the other dimensions. If, for example, the CTE of that bus bar causes a dimensional increase of 5%, then the length of the bus bar is increased by 50 millimeters while the width is increased by 0.2 millimeters and the thickness is increased by 0.025 millimeters. Accordingly, when one or both ends of the bus bar 110A are not in a fixed position, then the length of the bus bar 110A increases along the z-axis as illustrated by the bottom bus bar 110A in FIG. 4A increasing its length by a first amount 444 in the z-axis.

However, as illustrated in FIGS. 4B and 4C, when both ends of the bus bar are in fixed positions, like when they are in a module, the bus bar still increases in length when subjected to an increase in temperature, but it cannot extend in the z-axis and it instead buckles and deforms in other axes. For instance, FIG. 4B depicts partial cross-sectional views of another example solid bus bar undergoing an example thermal cycle. Here, the top bus bar 110B is similar to bus bar 110A of FIG. 4A except that both its first end 440B and second end 442B are in fixed positions such that they cannot move. When bus bar 110B is subjected to an increase in temperature, the length of the bus bar 110B increases, but because the first end 440B and second end 442B are in fixed positions, the bus bar 110B buckles and deforms in other directions, such as in the y-axis or x-axis, in order to accommodate this increase in length.

Similar to FIG. 4B, FIG. 4C depicts an illustration of the thermal expansion of a bus bar in a module. Here, simplified module 400 includes the flexible top sheet 112 and the flexible bottom sheet 114 along with the solid bus bar 110C in the sealed space 104; for clarity, the photovoltaic cells of the module 400 are not depicted. An encapsulant 130 is also seen in the sealed space 104 and interposed between the flexible top and bottom sheets 112 and 114, respectively. A directional legend is also depicted in FIG. 4A; the y-axis may be considered perpendicular to the flexible top sheet 112 and the flexible bottom sheet 114. Here, the first end 440C and second end 442C of the bus bar 110C are in fixed positions such that they cannot move so that when the bus bar 110C is subjected to an increase in temperature, the length of the bus bar 110C increases, but it buckles, deforms, and extends into at least the y-axis. This deformation by the bus bar 110C causes the plastic deformation of at least one of the other materials of the module 400 in the y-axis, such as the encapsulant 130, the flexible top sheet 112, the flexible bottom sheet 114, or the photovoltaic cells (not shown) as illustrated in FIG. 4C. When the temperature of the module 400 is decreased, the bus bar 110C returns to its original length, but the deformation of the other materials of the module remains and thus creates the bus bar bump.

A deformation of the module in the y-axis may be considered a bus bar bump regardless of whether the encapsulant, the flexible top sheet, the flexible bottom sheet, or the photovoltaic cells are caused to be plastically deformed. The deformed shape of the module depicted in FIG. 4C is an example of the bus bar bump. Such a deformation results in deviance from planarity of the flexible top sheet 112, of the flexible bottom sheet 114, or both. For example, referring to FIG. 4C, the flexible top sheet 112 has an interior surface 112B that contacts the encapsulant 130 and faces the photovoltaic cells and an exterior surface 112A that forms a part of the exterior surface of the module 400 and the flexible bottom sheet 114 has an interior surface 114B that contacts the encapsulant 130 and faces the photovoltaic cells and an exterior surface 114A that forms a part of the exterior surface of the module 400. After construction of the module 100, the exterior surface 112A of the flexible top sheet 112 is planar, i.e., it is a flat surface, and the exterior surface 114A of the flexible bottom sheet 114 is also planar. A bus bar bump causes the flexible top sheet 112, the flexible bottom sheet 114, or both to deform so that they are no longer flat. This may be a deviation from flatness by about 1%, 5%, or even about 10%, or any range in between these values.

It has been observed that this bus bar bump occurs when the solid metal bus bar is longer than about 1 meter; it generally does not occur at a length less than 1 meter so it may therefore not be a consideration for modules less than about 1 meter because the increase in buckling and deformation caused by the increased length due to thermal expansion does not create a bus bar bump in a module. Accordingly, modules that are the subject of this disclosure that are longer than 1 meter, such as between 1.7 meters and 6 meters experience the bus bar bump.

Presented herein as part of this disclosure are embodiments of flexible photovoltaic modules that include a bus bar configured to minimize or eliminate this bus bar bump. This type of bus bar may be the bus bar of the module discussed herein and shown in FIGS. 1-3 and may be arranged accordingly (e.g., electrically connected to the photovoltaic cell 102H in the second region 126 and to the first external electrical connector in the first region 120, and extending substantially the length of the module).

The bus bar of the present disclosure is not a solid metal band or strip as discussed above. Rather, the bus bar of the present disclosure is non-monolithic and includes metallic strands that are interlaced. Interlacing includes weaving, intertwining, braiding, and twisting. Weaving is the interlacing of strands passing in one direction with others at a right angle to them while braiding is the interlacing of strands together but not at right angles. In some embodiments, the interlacing may be at least three individual monolithic strands that are interlaced with each other, or twisted together. Such interlacing may include one central monolithic strand and a plurality of monolithic strands surrounding that central strand, all of which are interlaced with each other. In some embodiments, the individual monolithic strands may not be interlaced with each other, but rather they may be grouped into a plurality of groups, with each group having a particular number of monolithic strands, and it is these groups that are interlaced with each other. Each group may have the same number of monolithic strands as the other groups. In some embodiments, the interlacing of these metallic strands may be considered braiding, like with a braided wire, while in some other embodiments, the interlacing may be considered a plurality of wires bundled or wrapped together, like with a stranded wire. For example, a bus bar may have twelve groups that each have four individual wires, and the twelve groups are braided together.

In some embodiments, the bus bar with interlaced metallic strands may also be flattened. The flattening may occur by compressing the interlaced metallic strands, such as by drawing the interlaced strands between two rollers thereby pressing the interlaced metallic strands. The flattening may be a flattening of the individual metallic strands, the flattening of the interlaced structure itself, or both. For example, prior to flattening, the interlaced strands may each have circular cross-sectional areas and may be formed into a cylindrical braided wire, and during flattening, the wire is drawn through two rollers which flatten the cylindrical wire to a strip that does not have a cylindrical cross-sectional area and instead has an oblong or generally rectangular cross-sectional area. In some embodiments, this may flatten the individual strands, while in other embodiments this may only flatten the overall interlaced structure and not the individual strands. The cross-sectional area may not be an actual rectangle given that the interlaced strands are generally circular and there may be some gaps between each strand, but rather it may be considered to be encompassed by a rectangle such that the cross-sectional area of the bus bar is at least 75% of the rectangular cross-sectional area.

FIG. 8 depicts an example cross-sectional area of a bus bar 810 that has interlaced metallic strands. The view of FIG. 8 is along the z-axis (i.e., the length of the bus bar 810) and the cross-section slice is taken in the y-axis. The bus bar 810 includes 22 metallic strands 136 that are interlaced and each have an elliptical or generally circular cross-sectional areas. As can be seen, the cross-sectional area of the bus bar is encompassed by rectangle 138 such that at least 75% of the cross-sectional area of rectangle 138 includes the cross-sectional area of the bus bar 810. In some embodiments, the bus bar with interlaced metallic strands may be flattened in order to form such a cross-sectional shape.

The interlacing of the metallic strands of the bus bar enables the bus bar of the present disclosure to expand and contract in more directions and/or in more amounts than a sold bus bar. Such additional movement enables the bus bar of the present disclosure to move within at least the x- and/or z-directions which in turn prevents or reduces the buckling and deformation of the bus bar in the y-axis thereby preventing or reducing the bus bar bump.

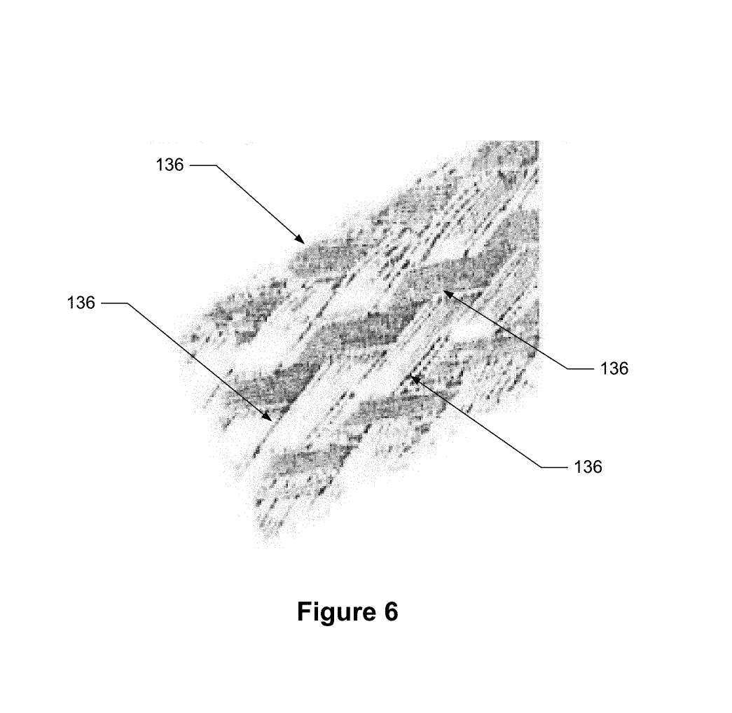

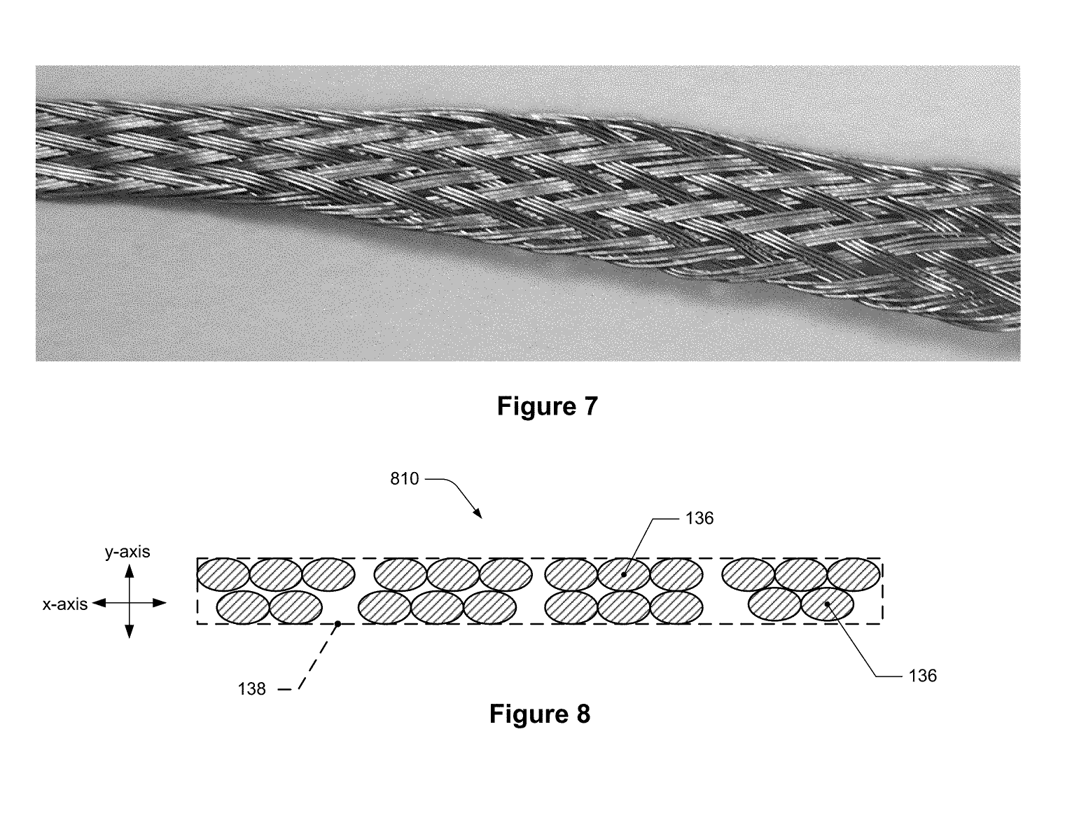

The metallic strands are a conductive metal or alloy, such as copper. In some embodiments, the metallic strands are plated by another conductive material, such as titanium nitride. The bus bar 110 may also include an external insulation, such as a polymer. FIGS. 6 and 7 depict photographs of portions of example uninsulated bus bars that include interlaced metallic strands. As can be seen in FIG. 6, some individual strands 136 are woven with each other; in FIG. 7, which is less magnified than that of FIG. 6, various interlaced strands are also depicted. Like described above, the bus bar of FIG. 7 includes a plurality of groups that are interlaced, or braided, and each of the groups includes a particular number of individual monolithic wires. For instance, item 136 in FIG. 7 is one group that includes a set of four individual strands and this one group is interlaced with some of the other groups. A bus bar that includes interlaced metallic strands still has a CTE that differs significantly from those of the surrounding components, but under thermal cycling, this type of bus bar does not expand like the solid bar described above and shown in FIGS. 4A-4C. Rather, this type of bus bar expands less or not at all in the y-axis and more in the x-axis than the solid metal bus bar, thereby causing little to no plastic deformation of the module in the y-axis. For instance, this type of bus bar causes little to no deformation to the flexible top sheet 112, the flexible bottom sheet 114, the photovoltaic cells 102, and the encapsulant 130 in the y-axis of FIGS. 1, 2, and 4A-4C. As a result, the bus bar bump in flexible modules is reduced or eliminated.

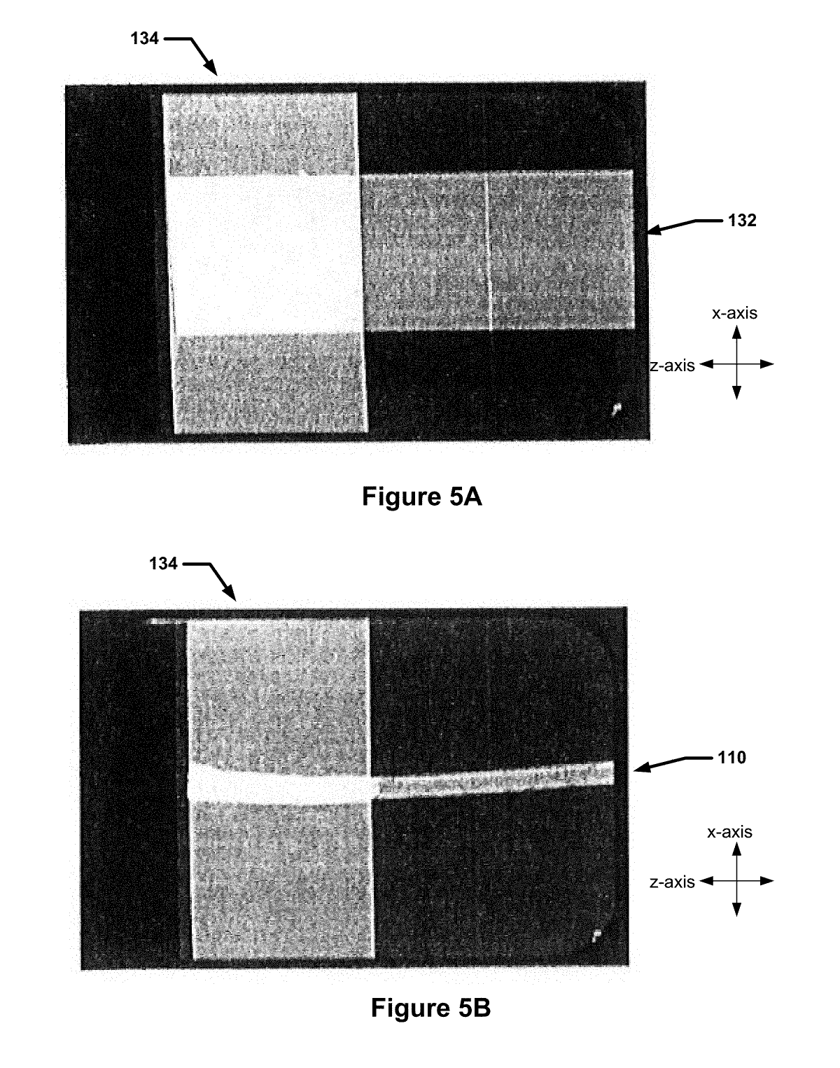

The thermal expansion of the solid metal bus bar and the bus bar that includes interlaced metallic strands in the x-axis is shown in FIGS. 5A and 5B, which depict top views of x-rays of metallic bus bars. FIG. 5A shows the top view of a solid metal copper band 132 (seen extending along the z-axis) positioned within a test section 134 (seen extending along the z-axis) of an example module that includes an encapsulant, a flexible top sheet, and a flexible bottom sheet. In FIG. 5B, the top view of a bus bar 110 of interlaced strands of copper (seen extending left to right in the Figure) positioned within the same simulated section 134 (seen extending vertically in the Figure) of a module can be seen. The view of these Figures is along the y-axis of FIGS. 4A-4C; these Figures also include the legend depicting the x- and z-axes. Both of these arrangements underwent thermal cycling and as can be seen, the bus bar of FIG. 5A experienced no perceptible thermal expansion along the x-axis, but the bus bar of FIG. 5B did have thermal expansion along the x-axis. This thermal expansion along the x-axis prevents or minimizes, at least in part, the formation of the bus bar bump because the thermal expansion of the bus bar in the z-axis is minimized or eliminated.

Accordingly, in some embodiments, the bus bar having interlaced metallic strands may deform less have an overall CTE in a direction perpendicular to the flexible top sheet (e.g., in the y-axis of FIGS. 4A-4C) that is less than or equal to the CTE of the flexible top sheet in that same direction; this bus bar may also have a CTE in that direction perpendicular to the flexible top sheet (e.g., in the y-axis) that is less than or equal to the CTE of the encapsulant in the direction perpendicular to the flexible top sheet. In some embodiments, it may be considered that the CTE of the bus bar is greater in a direction parallel to the flexible top sheet (e.g., in the x-axis of FIGS. 4A-5B) than the CTE of the bus bar in the direction perpendicular to the flexible top sheet (e.g., in the y-axis of FIGS. 4A-4C).

In some embodiments, a bus bar having interlaced metallic strands may fully eliminate the bus bar bump over a central region of the module, e.g., section 128 in FIG. 1, such that the outer surface of the flexible top sheet, the flexible bottom sheet, or both, within the central region may vary in planarity by less than or equal to 1%, less than or equal to 5%, or less than or equal to 10% of planar (i.e., of flat). Such variations in planarity are present after thermal cycling of the module; in other words, the thermal cycling of the module does not cause the bus bar to cause the formation of the bus bar bump. In some embodiments, the outer surface of the top sheet does not vary in planarity whatsoever in the central region. In some embodiments, the bus bar may be positioned between the flexible bottom sheet and the photovoltaic cells and a bus bar having interlaced metallic strands may fully eliminate the bus bar bump of the flexible bottom sheet, the flexible top sheet, or both such that the outer surface of the flexible bottom sheet, the flexible top sheet, or both, respectively, may vary in planarity within the central region by less than or equal to 1%, less than or equal to 5%, or less than or equal to 10% of planar (i.e., of flat). Again, this elimination of the bus bar bump occurs after thermal cycling of the module.

The length of the bus bar of the present disclosure, as discussed above, is greater than at least 1 meter because the bus bar bump does not occur for bus bars that are less than about 1 meter in length. In some embodiments, the bus bar extends substantially the length of the photovoltaic module (substantially here means within 15% of the length); some example lengths of the modules include about 1.6 meters to about 6 meters. The thickness of the bus bar (as measured in the y-axis) may be about 0.5 millimeters or less. As discussed above, for thin modules having a thickness of 1 millimeter or less, the bus bars must be less than this overall module thickness, such as about 0.5 millimeters. The width of the bus bar may (as measured in the x-axis), in some embodiments, be about 4 millimeters or about 5 millimeters.

The bus bar of the present disclosure also is able to conduct the current generated by the string of photovoltaic cells. This may include having a conductivity that enables the bus bar to carry a current of at least 3.0 amps, at least 3.5 amps, and between about 3.0 amps to about 13.6 amps, or about 125% of the fuse rating of a solar panel. The bus bar does not electrically interconnect two of the photovoltaic cells together and is not a current collector of the photovoltaic cells; instead the wire network 108 both collects the current from and interconnects the photovoltaic cells while the bus bar 110 acts as an electrical return line for the entire string of photovoltaic cells.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above described processes may be changed.

The subject matter of the present disclosure includes all novel and nonobvious combinations and sub-combinations of the various processes, systems and configurations, and other features, functions, acts, and/or properties disclosed herein, as well as any and all equivalents thereof.

Unless the context of this disclosure clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also generally include the plural or singular number respectively. When the word “or” is used in reference to a list of two or more items, that word covers all of the following interpretations of the word: any of the items in the list, all of the items in the list, and any combination of the items in the list. The term “implementation” refers to implementations of techniques and methods described herein, as well as to physical objects that embody the structures and/or incorporate the techniques and/or methods described herein.

What is claimed is:

1. A flexible photovoltaic module having a length and a width, the flexible photovoltaic module comprising:
a flexible top sheet;
a flexible bottom sheet;
a plurality of photovoltaic cells electrically connected to each other and positioned in a sealed space between the flexible top sheet and the flexible bottom sheet, wherein the sealed space includes a first region at a first end of the flexible photovoltaic module, a second region at a second end of the flexible photovoltaic module, and a central region interposed between the first region and the second region that encompasses at least 75% of the photovoltaic cells;
a first external electrical connector that extends into the first region and is electrically connected, in the first region, to the plurality of photovoltaic cells;
a second external electrical connector that extends into the first region; and
a bus bar that:
comprises interlaced copper strands and an external insulation,
has a length of at least 1 meter and a thickness of about 0.5 millimeters or less,
has a conductivity that can conduct at least 3.0 amps of current,
extends substantially the length of the flexible photovoltaic module and is positioned in the first region, the central region, and the second region, and
is electrically connected, in the first region, to the second external electrical connector, and, in the second region, to the plurality of photovoltaic cells.

2. The flexible photovoltaic module of claim 1, wherein an outer surface of the flexible top sheet within the central region varies in planarity by less than 5% of planar.

3. The flexible photovoltaic module of claim 2, wherein:
each of the photovoltaic cells comprises a photovoltaic layer and is positioned such that the photovoltaic layer faces the flexible top sheet, and
the bus bar is positioned in-between the plurality of photovoltaic cells and the flexible bottom sheet.

4. The flexible photovoltaic module of claim 1, wherein the interlaced copper strands are flattened.

5. The flexible photovoltaic module of claim 1, wherein an outer surface of the flexible bottom sheet within the central region varies in planarity by less than 5% of planar.

6. The flexible photovoltaic module of claim 1, wherein an outer surface of the flexible top sheet within the central region varies in planarity by less than 5% of planar and an outer surface of the flexible bottom sheet within the central region varies in planarity by less than 5% of planar.

7. The flexible photovoltaic module of claim 1, wherein the bus bar is configured to deform in a direction parallel to the flexible top sheet more than in a direction perpendicular to the flexible top sheet.

8. The flexible photovoltaic module of claim 1, wherein repeated heating and cooling of the flexible photovoltaic module does not cause the bus bar to plastically deform one or more of: the flexible top sheet and the flexible bottom sheet.

9. The flexible photovoltaic module of claim 1, wherein the length of the flexible photovoltaic module is at least 1.7 meters long.

10. The flexible photovoltaic module of claim 1, wherein:
the length of the flexible photovoltaic module is between about 1.7 meters long and 6 meter long, and
the length of the bus bar is at least 75% of the length of the flexible photovoltaic module.

11. The flexible photovoltaic module of claim 1, wherein the bus bar has a width of at least 4 millimeters.

12. The flexible photovoltaic module of claim 1, wherein the interlaced copper strands are plated by titanium nitride.

13. The flexible photovoltaic module of claim 1, wherein the first external electrical connector and the second external electrical connector have opposite polarities.

14. The flexible photovoltaic module of claim 1, wherein the plurality of photovoltaic cells are electrically connected to each other in series.

15. The flexible photovoltaic module of claim 14, wherein:
the plurality of photovoltaic cells consists of N photovoltaic cells,
the first photovoltaic cell is positioned in the first region, and
the Nth photovoltaic cell is positioned in the second region.

16. The flexible photovoltaic module of claim 15, wherein the bus bar is physically connected to the Nth photovoltaic cell.

17. The flexible photovoltaic module of claim 1, wherein the bus bar is an electrical return for the plurality of photovoltaic cells.

18. The flexible photovoltaic module of claim 1, further comprising a plurality of electrical interconnects, wherein:
the plurality of photovoltaic cells are electrically interconnected to each other by the plurality of electrical interconnects such that each electrical interconnect forms an electrical connection between two photovoltaic cells, and
the bus bar does not electrically interconnect two of the photovoltaic cells together.

19. The flexible photovoltaic module of claim 18, wherein:
each electrical interconnect is a current collector for each corresponding photovoltaic cell such that the current generated by each of the photovoltaic cells is collected by the plurality of electrical interconnects, and
the bus bar is not a current collector for the plurality of photovoltaic cells.

20. The flexible photovoltaic module of claim 1, wherein:
the first region comprises one photovoltaic cell,
the second region comprises another photovoltaic cell, and
the central region comprises the remaining photovoltaic cells of the plurality of photovoltaic cells.
